(19) United States
(12) Patent Application Publication
(10) Pub. No.: US 2017/0141248 A1
(43) Pub. Date: May 18, 2017

(54) ORGANIC VEHICLE FOR ELECTROCONDUCTIVE PASTE

(71) Applicant: Heraeus Precious Metals North America Conshohocken LLC, West Conshohocken, PA (US)

(72) Inventors: Lixin SONG, Blue Bell, PA (US); Toong J. SNG, Singapore (SG); Chi Long CHEN, Blue Bell, PA (US); YÍ ZHANG, West Windsor, NJ (US); Vineet DUE, Royersford, PA (US); David KAPP, Gibsonia, PA (US); YI YANG, Fort Washington, PA (US)

(21) Appl. No.: 15/317,235

(22) PCT Filed: Jun. 19, 2015
(86) PCT No.: PCT/US2015/036639

§ 371 Date: Dec. 8, 2016

Related U.S. Application Data
(60) Provisional application No. 62/014,858, filed on Jun. 20, 2014.

(51) Int. Cl. H01L 31/0224; C03C 8/18; C09D 11/033; C09D 11/08; H01B 1/22; C09D 11/52

(52) U.S. Cl. CPC H01L 31/022425; H01B 1/22; C09D 11/52; C09D 11/033; C09D 11/08; C03C 8/18; C03C 2207/00

(57) ABSTRACT

An organic vehicle comprising at least about 0.5 wt % and no more than about 45 wt % of at least one of a natural essential oil, based upon 100% total weight of the organic vehicle, at least about 0.5 wt % and no more than about 10 wt % of at least one resin, an organic solvent, and a thixotropic agent is provided. The invention also provides a solar cell and a method of forming a solar cell with the electroconductive paste of the invention.

### TECHNICAL FIELD

This invention relates to an organic vehicle used in the formulation of electroconductive pastes. In one aspect, the organic vehicle includes natural essential oil(s) which improve the printability and printed line uniformity of the electroconductive paste. The invention also relates to a solar cell produced from the electroconductive paste and a method of forming a solar cell.

### BACKGROUND

Solar cells are devices that convert the energy of light into electricity using the photovoltaic effect. Solar power is an attractive green energy source because it is sustainable and produces only non-polluting by-products. In operation, when light hits a solar cell, a fraction of the incident light is reflected by the surface and the remainder is transmitted into the solar cell. The photons of the transmitted light are absorbed by the solar cell, which is usually made of a semiconducting material such as silicon. The energy from the absorbed photons excites electrons of the semiconducting material from their atoms, generating electron-hole pairs. These electron-hole pairs are then separated by p-n junctions and collected by conductive electrodes which are applied on the solar cell surface. In this way, electricity may be conducted between interconnected solar cells.

Solar cells typically have electroconductive compositions applied to both their front and back surfaces which, when fired, form electrodes. While any known application methods may be used, these pastes are often applied to the substrate via screen printing. A typical electroconductive composition contains metallic particles, an inorganic component, and an organic vehicle. The composition of the organic vehicle may have an impact on the paste's printability, as well as the properties of the printed lines, both of which affect the performance of the solar cell. Specifically, narrower printed lines cover less of the silicon surface, thereby obstructing less sunlight, and taller lines provide a greater pathway for electrical current. Pastes that screen print well reduce the occurrence of screen clogging, which can create undesirable line breaks and areas of low paste deposition on the silicon surface.

Conventionally, electroconductive paste compositions have been formulated with various resins and thixotropic agents in order to control the printed line dimensions. These materials are effective at controlling line width (by minimizing the spread of the paste across the wafer surface), but also tend to inhibit the paste printability by restricting the flow of the paste through the openings in the screen. Accordingly, there is a need for electroconductive compositions which improve printed line dimensions without jeopardizing printability of the paste.

### SUMMARY

The organic vehicle of the invention provides an electroconductive paste with improved line dimension and printability.

In one aspect, the invention provides an organic vehicle for an electroconductive paste composition which comprises at least about 0.5 wt % and no more than about 45 wt % of at least one of a natural essential oil, based upon 100% total weight of the organic vehicle, at least about 0.5 wt % and no more than about 10 wt % of at least one resin, an organic solvent, and a thixotropic agent.

The invention also provides an electroconductive paste which comprises conductive metallic particles, glass frit, and the organic vehicle of the invention.

The invention further provides an electroconductive paste which comprises conductive metallic particles, glass frit, an organic vehicle comprising at least about 0.5 wt % and no more than about 10 wt % of at least one resin, based upon 100% total weight of the organic vehicle, an organic solvent, and a thixotropic agent, and at least about 0.01 wt % and no more than about 10 wt % of at least one natural essential oil, wherein the oil is added to the paste either together with the above-mentioned components or after the above-mentioned components have been combined.

Another aspect of the invention is a method of forming a solar cell comprising applying an electroconductive paste according to the invention to a surface of a silicon wafer and subjecting the electroconductive paste to one or more thermal treatment steps.

The invention also provides a solar cell formed according to the method of the invention.

### DETAILED DESCRIPTION

The organic vehicle of the invention may be useful as a component in any number of applications, including, but not limited to, electroconductive paste compositions. Such compositions may be used to form, for example, solar cells.

### Organic Vehicle

The organic vehicle of the invention provides the media by which the conductive metallic particles and glass frit are applied to the silicon surface to form a solar cell electrode. Preferred organic vehicles are solutions, emulsions or dispersions formed of one or more solvents, preferably organic solvent(s), which ensure that the components of the paste are present in a dissolved, emulsified or dispersed form. Organic vehicles which provide optimal stability of the components of the electroconductive composition and which provide the paste with suitable printability are preferred.

In one embodiment, the organic vehicle comprises at least one of an organic solvent, a resin (e.g., a polymer), a surfactant and a thixotropic agent, or any combination thereof. In a preferred embodiment, the organic vehicle comprises an organic solvent, resin, surfactant, thixotropic agent, and at least one of a natural essential oil. Without being bound by any particular theory, the natural essential oil is believed to allow for the formation of narrower, taller lines by controlling the paste wetting behavior on the screen emulsion, resulting in better line uniformity beyond what has been achieved by resins and/or thixotropic agents alone, without having a detrimental effect on paste printability.

In one embodiment, the organic vehicle is present in the electroconductive composition in an amount of at least about 0.1 wt %, preferably at least about 1 wt %, and most preferably at least about 5 wt %, based upon 100% total weight of the composition. At the same time, the organic vehicle is preferably no more than about 20 wt %, preferably no more than about 15 wt %, based upon 100% total weight of the composition.

In a preferred embodiment, the organic vehicle includes at least one of a natural essential oil. The natural essential oil may be, for example, olive oil, sunflower oil, corn oil, mustard oil, sesame oil, almond oil, peanut oil, canola oil, coconut oil, vegetable oil, and any other similar natural essential oil known to one skilled in the art. In one embodiment, the organic vehicle comprises at least about 0.5 wt % of the natural essential oil(s), preferably at least about 5 wt %, based upon 100% total weight of the organic vehicle. At the same time, the organic vehicle comprises no more than about 45 wt % of the natural essential oil(s), and preferably no more than about 35 wt %.

In a most preferred embodiment, the natural essential oil(s) include terpene compound(s). Suitable terpene compounds include, for example, lavender oil, spike oil, lavandin oil, lavender grosso oil, linalool, linalyl acetate, geraniol, isoeugenol, farnesol, linoleic acid, eugenol, citronellol, terpineol and its isomers, pinenes and its isomers, and any combination thereof.

In another embodiment, the natural essential oil(s) are incorporated into the electroconductive paste separately from the organic vehicle or any other paste components. The natural essential oil(s) may be added together with the other paste components, i.e., the conductive metallic particles, glass frit, and organic vehicle, or the natural essential oil(s) may be added to the paste composition once the paste components have already been combined. In this embodiment, the natural essential oil(s) is an additive, rather than a component of the organic vehicle.

As set forth above, the organic vehicle may also include at least one resin. Preferred resins are those which contribute to the formation of an electroconductive composition with favorable printability and viscosity. All resins which are known in the art, and which are considered to be suitable in the context of this invention, may be employed as the resin in the organic vehicle. Preferred resins include, but are not limited to, polymeric resins, monomeric resins, and resins which are a combination of polymers and monomers. Polymeric resins can also be copolymers wherein at least two different monomeric units are contained in a single molecule. Preferred polymeric resins are those which carry functional groups in the polymer main chain, those which carry functional groups off of the main chain, and those which carry functional groups both within the main chain and off of the main chain. Preferred polymers carrying functional groups in the main chain include, for example, polyesters, substituted polyesters, polycarbonates, substituted polycarbonates, polymers which carry cyclic groups in the main chain, poly-sugars, substituted poly-sugars, polyurethanes, substituted polyurethanes, polyamides, substituted polyamides, phenolic resins, substituted phenolic resins, copolymers of the monomers of one or more of the preceding polymers, optionally with other co-monomers, or a combination of at least two thereof. According to one embodiment, the resin may be polyvinyl butyral or polyethylene. Preferred polymers which carry cyclic groups in the main chain include, for example, polyvinylbutylate (PVB) and its derivatives and poly-terpineol and its derivatives or mixtures thereof. Preferred poly-sugars include, for example, cellulose and alkyl derivatives thereof, preferably methyl cellulose, ethyl cellulose, hydroxyethyl cellulose, propyl cellulose, hydroxypropyl cellulose, butyl cellulose and their derivatives and mixtures of at least two thereof. Other preferred polymers include, for example, cellulose ester resins, e.g., cellulose acetate propionate, cellulose acetate butyrate, and any combinations thereof. Preferred polymers which carry functional groups off of the main polymer chain include those which carry amide groups, those which carry acid and/or ester groups, often called acrylic resins, or polymers which carry a combination of aforementioned functional groups, or a combination thereof. Preferred polymers which carry amide off of the main chain include, for example, polyvinyl pyrrolidone (PVP) and its derivatives. Preferred polymers which carry acid and/or ester groups off of the main chain include, for example, polyacrylic acid and its derivatives, polymethacrylate (PMA) and its derivatives or polymethylmethacrylate (PMMA) and its derivatives, or a mixture thereof. Preferred monomeric resins are ethylene glycol based monomers, terpineol resins or rosin derivatives, or a mixture thereof. Preferred monomeric resins based on ethylene glycol are those with ether groups, ester groups, or those with an ether group and an ester group, preferred ether groups being methyl, ethyl, propyl, butyl, pentyl hexyl and higher alkyl ethers, the preferred ester group being acetate and its alkyl derivatives, preferably ethylene glycol monobutylether monoacetate or a mixture thereof. Alkyl cellulose, preferably ethyl cellulose, its derivatives, and mixtures thereof with other resins from the preceding list of resins or otherwise, are the most preferred resins.

The resin may be present in an amount of at least about 0.5 wt %, preferably at least about 1 wt %, and most preferably at least about 3 wt %, based upon 100% total weight of the organic vehicle. At the same time, the resin may be present in an amount of no more than about 10 wt %, and preferably no more than about 8 wt %, based upon 100% total weight of the organic vehicle. As compared to conventional pastes, a resin content of above 3 wt % is fairly high, but the presence of the natural essential oil is believed to counter the effect of the high resin content on the printability of the paste.

Preferred solvents are components which are removed from the paste to a significant extent during firing. Preferably, they are present after firing with an absolute weight reduced by at least about 80% compared to before firing, preferably reduced by at least about 95% compared to before firing. Preferred solvents are those which contribute to favorable viscosity and printability characteristics. All solvents which are known in the art, and which are considered to be suitable in the context of this invention, may be employed as the solvent in the organic vehicle. Preferred solvents are those which exist as a liquid under standard ambient temperature and pressure (SATP) (298.15 K, 25° C., 77° F.), 100 kPa (14.504 psi, 0.986 atm), preferably those with a boiling point above about 90° C. and a melting point above about −20° C. Preferred solvents are polar or non-polar, protic or aprotic, aromatic or non-aromatic. Preferred solvents include, for example, mono-alcohols, di-alcohols, poly-alcohols, mono-esters, di-esters, poly-esters, mono-ethers, di-ethers, poly-ethers, solvents which comprise at least one or more of these categories of functional group, optionally comprising other categories of functional group, preferably cyclic groups, aromatic groups, unsaturated bonds, alcohol groups with one or more O atoms replaced by heteroatoms, ether groups with one or more O atoms replaced by heteroatoms, esters groups with one or more O atoms replaced by heteroatoms, and mixtures of two or more of the aforementioned solvents. Preferred esters in this context include, for example, di-alkyl esters of adipic acid, preferred alkyl constituents being methyl, ethyl, propyl, butyl, pentyl, hexyl and higher alkyl groups or combinations of two different such alkyl groups, preferably dimethyladipate, and mixtures of two or more adipate esters. Preferred ethers in this context include, for example, diethers, preferably dialkyl ethers of ethylene glycol, preferred alkyl constituents being methyl, ethyl, propyl, butyl, pentyl, hexyl and higher alkyl groups or combinations of two different such alkyl groups, and mixtures of two diethers. Preferred alcohols in this context include, for example, primary, secondary and tertiary alcohols, preferably tertiary alcohols, terpineol and its derivatives being preferred, or a mixture of two or more alcohols. Preferred solvents which combine more than one different functional groups are 2,2,4-trimethyl-1,3-pentanediol monoisobutyrate, often called texanol, and its derivatives, 2-(2-ethoxyethoxy)ethanol, often known as carbitol, its alkyl derivatives, preferably methyl, ethyl, propyl, butyl, pentyl, and hexyl carbitol, preferably hexyl carbitol or butyl carbitol, and acetate derivatives thereof, preferably butyl carbitol acetate, or mixtures of at least two of the aforementioned. In a preferred embodiment, the solvent includes at least one of glycol ether (e.g., Dowanol® DB, Dowanol® EB, diglyme, and butyl diglyme), texanol, ester alcohol, or any combination thereof.

The organic solvent may be present in an amount of at least about 50 wt %, and more preferably at least about 60 wt %, and more preferably at least about 70 wt %, based upon 100% total weight of the organic vehicle. At the same time, the organic solvent may be present in an amount of no more than about 95 wt %, and more preferably no more than about 90 wt %, based upon 100% total weight of the organic vehicle.

The organic vehicle may also comprise one or more surfactants, thixotropic agents, and/or additives. Preferred surfactants are those which contribute to the formation of an electroconductive composition with favorable printability and viscosity characteristics. All surfactants which are known in the art, and which are considered to be suitable in the context of this invention, may be employed as the surfactant in the organic vehicle. Preferred surfactants are those based on linear chains, branched chains, aromatic chains, fluorinated chains, siloxane chains, polyether chains and combinations thereof. Preferred surfactants include, but are not limited to, single chained, double chained or poly chained polymers. Preferred surfactants may have non-ionic, anionic, cationic, amphiphilic, or zwitterionic heads. Preferred surfactants may be polymeric and monomeric or a mixture thereof. Preferred surfactants may have pigment affinic groups, preferably hydroxyfunctional carboxylic acid esters with pigment affinic groups (e.g., DISPERBYK®-108, manufactured by BYK USA, Inc.), acrylate copolymers with pigment affinic groups (e.g., DISPERBYK®-116, manufactured by BYK USA, Inc.), modified polyethers with pigment affinic groups (e.g., TEGO® DISPERS 655, manufactured by Evonik Tego Chemie GmbH), and other surfactants with groups of high pigment affinity (e.g., Duomeen TDO® manufactured by Akzo Nobel N.V.). Other preferred polymers not in the above list include, but are not limited to, polyethylene oxide, polyethylene glycol and its derivatives, and alkyl carboxylic acids and their derivatives or salts, or mixtures thereof. The preferred polyethylene glycol derivative is poly(ethyleneglycol)acetic acid. Preferred alkyl carboxylic acids are those with fully saturated and those with singly or poly unsaturated alkyl chains or mixtures thereof. Preferred carboxylic acids with saturated alkyl chains are those with alkyl chains lengths in a range from about 8 to about 20 carbon atoms, preferably C₉H₉COOH (capric acid), C₁₁H₂₃COOH (lauric acid), C₁₃H₂₇COOH (myristic acid) C₁₅H₃₁COOH (palmitic acid), C₁₇H₃₅COOH (stearic acid), or salts or mixtures thereof. Preferred carboxylic acids with unsaturated alkyl chains are C₁₈H₃₄O₂ (oleic acid) and C₁₈H₃₂O₂ (linoleic acid).

The surfactant may be at least about 0.5 wt %, based upon 100% total weight of the organic vehicle. At the same time, the surfactant is preferably no more than about 10 wt %, and preferably no more than about 8 wt %, based upon 100% total weight of the organic vehicle.

The organic vehicle may also comprise a thixotropic agent. Any thixotropic agent known to one having ordinary skill in the art may be used with the organic vehicle of the invention. For example, without limitation, thixotropic agents may be derived from natural origin or they may be synthesized. Preferred thixotropic agents include, but are not limited to, castor oil and its derivatives, inorganic clays, polyamides and its derivatives, fumed silica, carboxylic acid derivatives, preferably fatty acid derivatives (e.g., C₉H₁₉COOH (capric acid), C₁₁H₂₃COOH (lauric acid), C₁₃H₂₇COOH (myristic acid) C₁₅H₃₁COOH (palmitic acid), C₁₇H₃₅COOH (stearic acid) C₁₈H₃₄O₂ (oleic acid), C₁₈H₃₂O₂ (linoleic acid)), or combinations thereof. Commercially available thixotropic agents, such as, for example, Thixotrol® MAX, Thixotrol® ST, or THIXCIN® E, may also be used.

According to one embodiment, the organic vehicle comprises at least about 1 wt % thixotropic agent, and preferably at least about 7 wt %, based upon 100% total weight of the organic vehicle. At the same time, the organic vehicle preferably includes no more than about 15 wt % thixotropic agent, preferably no more than about 14 wt %, based upon 100% total weight of the organic vehicle.

Preferred additives in the organic vehicle are those materials which are distinct from the aforementioned components and which contribute to favorable properties of the electroconductive composition, such as advantageous viscosity, printability, and stability characteristics. Additives known in the art, and which are considered to be suitable in the context of the invention, may be used. Preferred additives include, but are not limited to, viscosity regulators, stabilizing agents, inorganic additives, thickeners, emulsifiers, dispersants and pH regulators. Where present, such additives are preferably no more than about 15 wt %, based upon 100% total weight of the organic vehicle.

The formulation of the organic vehicle may have an effect on the viscosity of the electroconductive paste composition, which in turn may affect its printability. If the viscosity is too high, the paste may not transfer well through the screen mesh and line breaks or low spots may occur. If the viscosity is too low, the paste may be too fluid, causing the printing lines to spread and the aspect ratio to decrease. As set forth herein, to measure viscosity of the electroconductive paste, a Brookfield HBDV-III Digital Rheometer equipped with a CP-44Y sample cup and a #51 cone was used. The temperature of the sample was maintained at 25° C. using a TC-502 circulating temperature bath. The measurement gap was set at 0.026 mm with a sample volume of approximately 0.5 ml. The sample was allowed to equilibrate for two minutes, and then a constant rotational speed of 1.0 rpm was applied for one minute. The viscosity of the sample after this interval was reported in units of kcps.

According to one embodiment, the viscosity of the electroconductive composition is preferably at least 50kcps and no more than about 400 kcps.

### Conductive Metallic Particles

The electroconductive composition also comprises conductive metallic particles. Preferred conductive metallic particles are those which exhibit optimal conductivity and which effectively sinter upon firing, such that they yield electrodes with high conductivity. Conductive metallic particles known in the art suitable for use in forming solar cell electrodes are preferred. Preferred metallic particles include, but are not limited to, elemental metals, alloys, metal derivatives, mixtures of at least two metals, mixtures of at least two alloys or mixtures of at least one metal with at least one alloy.

The electroconductive paste may comprise at least 35 wt % metallic particles, preferably at least 50 wt %, more preferably at least 70 wt %, and most preferably at least 80 wt %, based upon 100% total weight of the paste. At the same time, the electroconductive paste preferably includes no more than about 99 wt % metallic particles, preferably no more than about 95 wt %, based upon 100% total weight of the paste. Electroconductive pastes having a metallic particle content below 35 wt % may not provide sufficient electrical conductivity and adhesion, while electroconductive pastes having a metallic particle content above 95 wt % may have a viscosity which is too high for suitable screen printing.

Metals which may be employed as the metallic particles include at least one of silver, copper, gold, aluminum, nickel, platinum, palladium, molybdenum, and mixtures or alloys thereof. In a preferred embodiment, the metallic particles are silver. The silver may be present as elemental silver, a silver alloy, or silver derivate. Suitable silver derivatives include, for example, silver alloys and/or silver salts, such as silver halides (e.g., silver chloride), silver oxide, silver nitrate, silver acetate, silver trifluoroacetate, silver orthophosphate, and combinations thereof. In another embodiment, the metallic particles may comprise a metal or alloy coated with one or more different metals or alloys, for example silver particles coated with aluminum or copper particles coated with silver.

The metallic particles may be present with a surface coating, either organic or inorganic. Any such coating known in the art, and which is considered to be suitable in the context of the invention, may be employed on the metallic particles. Preferred organic coatings are those coatings which promote dispersion into the organic vehicle. Preferred inorganic coatings are those coatings which regulate sintering and promote adhesive performance of the resulting electroconductive paste. If such a coating is present, it is preferred that the coating correspond to no more than about 5 wt %, preferably no more than about 2 wt %, and most preferably no more than about 1 wt %, based on 100% total weight of the metallic particles.

The conductive particles can exhibit a variety of shapes, sizes, and specific surface areas. Some examples of shapes include, but are not limited to, spherical, angular, elongated (rod or needle like) and flat (sheet like). Conductive metallic particles may also be present as a combination of particles with different shapes, such as, for example, a combination of spherical metallic particles and flake-shaped metallic particles.

Another characteristic of the metallic particles is its average particle size, d₅₀. The d₅₀ is the median diameter or the medium value of the particle size distribution. It is the value of the particle diameter at 50% in the cumulative distribution. Particle size distribution may be measured via laser diffraction, dynamic light scattering, imaging, electrophoretic light scattering, or any other methods known in the art. Specifically, particle size according to the invention is determined in accordance with ISO 13317-3:2001. As set forth herein, a Horiba LA-910 Laser Diffraction Particle Size Analyzer connected to a computer with an LA-910 software program is used to determine the median particle diameter. The relative refractive index of the metallic particle is chosen from the LA-910 manual and entered into the software program. The test chamber is filled with deionized water to the proper fill line on the tank. The solution is then circulated by using the circulation and agitation functions in the software program. After one minute, the solution is drained. This is repeated an additional time to ensure the chamber is clean of any residual material. The chamber is then filled with deionized water for a third time and allowed to circulate and agitate for one minute. Any background particles in the solution are eliminated by using the blank function in the software. Ultrasonic agitation is then started, and the metallic particles are slowly added to the solution in the test chamber until the transmittance bars are in the proper zone in the software program. Once the transmittance is at the correct level, the laser diffraction analysis is run and the particle size distribution of the metallic component is measured and given as d₅₀.

It is preferred that the median particle diameter d₅₀ of the metallic particles be at least about 0.1 μm, and preferably at least about 0.5 μm. At the same time, the d₅₀ is preferably no more than about 5 μm, and more preferably no more than about 3 μm.

Another way to characterize the shape and surface of a particle is by its specific surface area. Specific surface area is a property of solids equal to the total surface area of the material per unit mass, solid, or bulk volume, or cross sectional area. It is defined either by surface area divided by mass (with units of m²/g) or surface area divided by volume (units of m⁻¹). The specific surface area may be measured by the BET (Brunauer-Emmett-Teller) method, which is known in the art. As set forth herein, BET measurements are made in accordance with DIN ISO 9277:1995. A Monosorb Model MS-22 instrument (manufactured by Quantachrome Instruments), which operates according to the SMART method (Sorption Method with Adaptive dosing Rate), is used for the measurement. As a reference material, aluminum oxide (available from Quantachrome Instruments as surface area reference material Cat. No. 2003) is used. Samples are prepared for analysis in the built-in degas station. Flowing gas (30% N₂ and 70% He) sweeps away impurities, resulting in a clean surface upon which adsorption may occur. The sample can be heated to a user-selectable temperature with the supplied heating mantle. Digital temperature control and display are mounted on the instrument front panel. After degassing is complete, the sample cell is transferred to the analysis station. Quick connect fittings automatically seal the sample cell during transfer, and the system is then activated to commence the analysis. A dewar flask filled with coolant is manually raised, immersing the sample cell and causing adsorption. The instrument detects when adsorption is complete (2-3 minutes), automatically lowers the dewar flask, and gently heats the sample cell back to room temperature using a built-in hot-air blower. As a result, the desorbed gas signal is displayed on a digital meter and the surface area is directly presented on a front panel display. The entire measurement (adsorption and desorption) cycle typically requires less than six minutes. The technique uses a high sensitivity, thermal conductivity detector to measure the change in concentration of an adsorbate/inert carrier gas mixture as adsorption and desorption proceed. When integrated by the on-board electronics and compared to calibration, the detector provides the volume of gas adsorbed or desorbed. For the adsorptive measurement, N₂ 5.0 with a molecular cross-sectional area of 0.162 nm² at 77K is used for the calculation. A one-point analysis is performed and a built-in microprocessor ensures linearity and automatically computes the sample's BET surface area in m²/g.

According to one embodiment, the metallic particles may have a specific surface area of at least about 0.1 m²/g, preferably at least about 0.2 m²/g. At the same time, the specific surface area is preferably no more than 10 m²/g, and more preferably no more than about 5 m²/g.

### Glass Frit

The glass frit of the electroconductive paste acts as an adhesion media, facilitating the bonding between the conductive particles and the silicon substrate, and thus providing reliable electrical contact. Specifically, the glass frit etches through the surface layers (e.g., antireflective layer) of the silicon substrate, such that effective electrical contact can be made between the electroconductive paste and the silicon wafer.

According to one embodiment, the electroconductive paste includes at least about 0.5 wt % glass frit, and preferably at least about 1 wt %, based upon 100% total weight of the paste. At the same time, the paste preferably includes no more than about 15 wt % glass frit, preferably no more than about 10 wt %, and most preferably no more than about 6 wt %, based upon 100% total weight of the electroconductive paste.

Preferred glass frits are powders of amorphous or partially crystalline solids which exhibit a glass transition. The glass transition temperature T_{g} is the temperature at which an amorphous substance transforms from a rigid solid to a partially mobile undercooled melt upon heating. Methods for the determination of the glass transition temperature are well known to the person skilled in the art. Specifically, the glass transition temperature T_{g} may be determined using a DSC apparatus SDT Q600 (commercially available from TA Instruments) which simultaneously records differential scanning calorimetry (DSC) and thermogravimetric analysis (TGA) curves. The instrument is equipped with a horizontal balance and furnace with a platinum/platinum-rhodium (type R) thermocouple. The sample holders used are aluminum oxide ceramic crucibles with a capacity of about 40-90 μl. For the measurements and data evaluation, the measurement software Q Advantage; Thermal Advantage Release 5.4.0 and Universal Analysis 2000, version 4.5A Build 4.5.0.5 is applied respectively. As pan for reference and sample, aluminum oxide pan having a volume of about 85 μl is used. An amount of about 10-50 mg of the sample is weighted into the sample pan with an accuracy of 0.01 mg. The empty reference pan and the sample pan are placed in the apparatus, the oven is closed and the measurement started. A heating rate of 10 K/min is employed from a starting temperature of 25° C. to an end temperature of 1000° C. The balance in the instrument is always purged with nitrogen (N₂ 5.0) and the oven is purged with synthetic air (80% N₂ and 20% O₂ from Linde) with a flow rate of 50 ml/min. The first step in the DSC signal is evaluated as glass transition using the software described above, and the determined onset value is taken as the temperature for T_{g}.

Preferably, the T_{g} is below the desired firing temperature of the electroconductive paste. According to the invention, preferred glass frits have a T_{g} of at least about 200° C., and preferably at least about 250° C. At the same time, preferred glass frits have a T_{g} of no more than about 900° C., preferably no more than about 800° C., and most preferably no more than about 700° C.

The glass frit may include elements, oxides, compounds which generate oxides upon heating, and/or mixtures thereof. According to one embodiment, the glass frit is lead-based and may include lead oxide or other lead-based compounds including, but not limited to, salts of lead halides, lead chalcogenides, lead carbonate, lead sulfate, lead phosphate, lead nitrate and organometallic lead compounds or compounds that can form lead oxides or salts during thermal decomposition, or any combinations thereof. In another embodiment, the glass frit may be lead-free. The term “lead-free” indicates that the glass frit has less than 0.5 wt % lead, based upon 100% total weight of the glass frit. The lead-free glass frit may include other oxides or compounds known to one skilled in the art, including, but not limited to, silicon, boron, aluminum, bismuth, lithium, sodium, magnesium, zinc, titanium, zirconium oxides, or compounds thereof.

In addition to the components recited above, the glass frit may also comprise other oxides or other compounds of magnesium, nickel, tellurium, tungsten, zinc, gadolinium, antimony, cerium, zirconium, titanium, manganese, lead, tin, ruthenium, silicon, cobalt, iron, copper, bismuth, boron, and chromium, or any combination of at least two thereof, compounds which can generate those metal oxides upon firing, or a mixture of at least two of the aforementioned metals, a mixture of at least two of the aforementioned oxides, a mixture of at least two of the aforementioned compounds which can generate those metal oxides on firing, or mixtures of two or more of any of the above mentioned. Other materials which may be used to form the inorganic oxide particles include, but are not limited to, germanium oxide, vanadium oxide, molybdenum oxide, niobium oxide, indium oxide, other alkaline and alkaline earth metal (e.g., potassium, rubidium, caesium, calcium, strontium, and barium) compounds, rare earth oxides (e.g., lanthanum oxide, cerium oxides), and phosphorus oxides.

It is well known to the person skilled in the art that glass frit particles can exhibit a variety of shapes, sizes, and surface area to volume ratios. The glass particles may exhibit the same or similar shapes (including length:width:thickness ratio) as may be exhibited by the conductive metallic particles, as discussed herein. Glass frit particles with a shape, or combination of shapes, which favor improved electrical contact of the produced electrode are preferred. It is preferred that the median particle diameter d₅₀ of the glass frit particles (as set forth above with respect to the conductive metallic particles) be at least about 0.1 μm. At the same time, it is preferred that the d₅₀ of the glass frit be no more than about 10 μm, more preferably no more than about 5 μm, and most preferably no more than about 3.5 μm. In one embodiment, the glass frit particles have a specific surface area of at least about 0.5 m²/g, preferably at least about 1 m²/g, and most preferably at least about 2 m²/g. At the same time, it is preferred that the specific surface area be no more than about 15 m²/g, preferably no more than about 10 m²/g.

According to another embodiment, the glass frit particles may include a surface coating. Any such coating known in the art and which is considered to be suitable in the context of the invention can be employed on the glass frit particles. Preferred coatings according to the invention include those coatings which promote dispersion of the glass in the organic vehicle and improved contact of the electroconductive paste. If such a coating is present, it is preferred that the coating correspond to no more than about 10 wt %, preferably no more than about 8 wt %, most preferably no more than about 5 wt %, in each case based on the total weight of the glass frit particles.

### Additives

Preferred additives are components added to the paste, in addition to the other components explicitly mentioned, which contribute to increased electrical performance of the paste, of the electrodes produced thereof, or of the resulting solar cell. In addition to additives present in the glass frit and in the vehicle, additives can also be present in the electroconductive paste separately. Preferred additives include, but are not limited to, thixotropic agents, viscosity regulators, emulsifiers, stabilizing agents or pH regulators, inorganic additives, thickeners and dispersants, or a combination of at least two thereof. Preferred inorganic organometallic additives include, but are not limited to, Mg, Ni, Te, W, Zn, Mg, Gd, Ce, Zr, Ti, Mn, Sn, Ru, Co, Fe, Rh, V, Y, Sb, P, Cu and Cr or a combination of at least two thereof, preferably Zn, Sb, Mn, Ni, W, Te, Rh, V, Y, Sb, P and Ru, or a combination of at least two thereof, oxides thereof, compounds which can generate those metal oxides on firing, or a mixture of at least two of the aforementioned metals, a mixture of at least two of the aforementioned oxides, a mixture of at least two of the aforementioned compounds which can generate those metal oxides on firing, or mixtures of two or more of any of the above mentioned. In a preferred embodiment, the electroconductive paste comprises zinc oxide.

According to one embodiment, the paste may include at least about 0.1 wt % additive(s). At the same time, the paste preferably includes no more than about 10 wt % additive(s), preferably no more than about 5 wt %, and most preferably no more than about 2 wt %, based upon 100% total weight of the paste.

### Forming the Electroconductive Paste Composition

To form an electroconductive paste, the glass frit materials are combined with the conductive metallic particles and organic vehicle using any method known in the art for preparing a paste composition. The method of preparation is not critical, as long as it results in a homogenously dispersed paste. The components can be mixed, such as with a mixer, then passed through a three roll mill, for example, to make a dispersed uniform paste. In addition to mixing all of the components together simultaneously, the raw glass frit materials can be co-milled with silver particles, for example, in a ball mill for 2-24 hours to achieve a homogenous mixture of glass frit and silver particles, which are then mixed with the organic vehicle.

### Solar Cells

The invention also relates to a solar cell. In one embodiment, the solar cell comprises a semiconductor substrate (e.g., a silicon wafer) and an electroconductive paste composition according to any of the embodiments described herein.

In another aspect, the invention relates to a solar cell prepared by a process which includes applying an electroconductive paste composition according to any of the embodiments described herein to a semiconductor substrate (e.g., a silicon wafer) and firing the semiconductor substrate.

### Silicon Wafer

Preferred wafers according to the invention have regions, among other regions of the solar cell, capable of absorbing light with high efficiency to yield electron-hole pairs and separating holes and electrons across a boundary with high efficiency, preferably across a p-n junction boundary. Preferred wafers according to the invention are those comprising a single body made up of a front doped layer and a back doped layer.

Preferably, the wafer comprises appropriately doped tetravalent elements, binary compounds, tertiary compounds or alloys. Preferred tetravalent elements in this context include, but are not limited to, silicon, germanium, or tin, preferably silicon. Preferred binary compounds include, but are not limited to, combinations of two or more tetravalent elements, binary compounds of a group III element with a group V element, binary compounds of a group II element with a group VI element or binary compounds of a group IV element with a group VI element. Preferred combinations of tetravalent elements include, but are not limited to, combinations of two or more elements selected from silicon, germanium, tin or carbon, preferably SiC. The preferred binary compounds of a group III element with a group V element is GaAs. According to a preferred embodiment of the invention, the wafer is silicon. The foregoing description, in which silicon is explicitly mentioned, also applies to other wafer compositions described herein.

The p-n junction boundary is located where the front doped layer and back doped layer of the wafer meet. In an n-type solar cell, the back doped layer is doped with an electron donating n-type dopant and the front doped layer is doped with an electron accepting or hole donating p-type dopant. In a p-type solar cell, the back doped layer is doped with p-type dopant and the front doped layer is doped with n-type dopant. According to a preferred embodiment of the invention, a wafer with a p-n junction boundary is prepared by first providing a doped silicon substrate and then applying a doped layer of the opposite type to one face of that substrate.

The doped silicon substrate can be prepared by any method known in the art and considered suitable for the invention. Preferred sources of silicon substrates according to the invention include, but are not limited to, mono-crystalline silicon, multi-crystalline silicon, amorphous silicon and upgraded metallurgical silicon, most preferably mono-crystalline silicon or multi-crystalline silicon. Doping to form the doped silicon substrate can be carried out simultaneously by adding the dopant during the preparation of the silicon substrate, or it can be carried out in a subsequent step. Doping subsequent to the preparation of the silicon substrate can be carried out by gas diffusion epitaxy, for example. Doped silicon substrates are also readily commercially available. According to one embodiment, the initial doping of the silicon substrate may be carried out simultaneously to its formation by adding dopant to the silicon mix. According to another embodiment, the application of the front doped layer and the highly doped back layer, if present, may be carried out by gas-phase epitaxy. This gas phase epitaxy is preferably carried out at a temperature of at least about 500° C., preferably at least about 600° C., and most preferably at least about 650° C. At the same time, the temperature is preferably no more than about 900° C., preferably no more than about 800° C., and most preferably no more than about 750° C. The gas phase epitaxy is preferably carried out at a pressure of at least about 2 kPa, preferably at least about 10 kPa, and most preferably at least about 40 kPa. At the same, the pressure is preferably no more than about 100 kPa, preferably no more than about 80 kPa, and most preferably no more than about 70 kPa.

It is known in the art that silicon substrates can exhibit a number of shapes, surface textures and sizes. The shape of the substrate may include cuboid, disc, wafer and irregular polyhedron, to name a few. According to a preferred embodiment of the invention, the wafer is a cuboid with two dimensions which are similar, preferably equal, and a third dimension which is significantly smaller than the other two dimensions. The third dimension may be at least 100 times smaller than the first two dimensions. Further, silicon substrates with rough surfaces are preferred. One way to assess the roughness of the substrate is to evaluate the surface roughness parameter for a sub-surface of the substrate, which is small in comparison to the total surface area of the substrate, preferably less than about one hundredth of the total surface area, and which is essentially planar. The value of the surface roughness parameter is given by the ratio of the area of the sub-surface to the area of a theoretical surface formed by projecting that sub-surface onto the flat plane best fitted to the sub-surface by minimizing mean square displacement. A higher value of the surface roughness parameter indicates a rougher, more irregular surface and a lower value of the surface roughness parameter indicates a smoother, more even surface. According to the invention, the surface roughness of the silicon substrate is preferably modified so as to produce an optimum balance between a number of factors including, but not limited to, light absorption and adhesion to the surface.

The two larger dimensions of the silicon substrate can be varied to suit the application required of the resultant solar cell. It is preferred according to the invention for the thickness of the silicon wafer to be below about 0.5 mm, more preferably below about 0.3 mm, and most preferably below about 0.2 mm. Some wafers have a minimum thickness of 0.01 mm or more.

It is preferred that the front doped layer be thin in comparison to the back doped layer. It is also preferred that the front doped layer have a thickness of at least about 0.1 μm, and preferably no more than about 10 μm, preferably no more than about 5 μm, and most preferably no more than about 2 μm.

A highly doped layer can be applied to the back face of the silicon substrate between the back doped layer and any further layers. Such a highly doped layer is of the same doping type as the back doped layer and such a layer is commonly denoted with a+(n+-type layers are applied to n-type back doped layers and p+-type layers are applied to p-type back doped layers). This highly doped back layer serves to assist metallization and improve electroconductive properties. It is preferred according to the invention for the highly doped back layer, if present, to have a thickness of at least 1 μm, and preferably no more than about 100 μm, preferably no more than about 50 μm and most preferably no more than about 15 μm.

### Dopants

Preferred dopants are those which, when added to the silicon wafer, form a p-n junction boundary by introducing electrons or holes into the band structure. It is preferred that the identity and concentration of these dopants is specifically selected so as to tune the band structure profile of the p-n junction and set the light absorption and conductivity profiles as required. Preferred p-type dopants include, but are not limited to, those which add holes to the silicon wafer band structure. All dopants known in the art and which are considered suitable in the context of the invention can be employed as p-type dopants. Preferred p-type dopants include, but are not limited to, trivalent elements, particularly those of group 13 of the periodic table. Preferred group 13 elements of the periodic table in this context include, but are not limited to, boron, aluminum, gallium, indium, thallium, or a combination of at least two thereof, wherein boron is particularly preferred.

Preferred n-type dopants are those which add electrons to the silicon wafer band structure. Preferred n-type dopants are elements of group 15 of the periodic table. Preferred group 15 elements of the periodic table in this context include, but are not limited to, nitrogen, phosphorus, arsenic, antimony, bismuth or a combination of at least two thereof, wherein phosphorus is particularly preferred.

As described above, the various doping levels of the p-n junction can be varied so as to tune the desired properties of the resulting solar cell. Doping levels are measured using secondary ion mass spectroscopy.

According to certain embodiments, the semiconductor substrate (i.e., silicon wafer) exhibits a sheet resistance above about 60 Ω/□, such as above about 65 Ω/□, 70 Ω/□, 90 Ω/□ or 100 Ω/□. For measuring the sheet resistance of a doped silicon wafer surface, the device “GP4-Test Pro” equipped with software package “GP-4 Test 1.6.6 Pro” (available from GP Solar GmbH) is used. For the measurement, the four point measuring principle is applied. The two outer probes apply a constant current and two inner probes measure the voltage. The sheet resistance is deduced using the Ohmic law in Ω/□. To determine the average sheet resistance, the measurement is performed on 25 equally distributed spots of the wafer. In an air conditioned room with a temperature of 22±1° C., all equipment and materials are equilibrated before the measurement. To perform the measurement, the “GP-Test.Pro” is equipped with a 4-point measuring head (Part Number 04.01.0018) with sharp tips in order to penetrate the anti-reflection and/or passivation layers. A current of 10 mA is applied. The measuring head is brought into contact with the non metalized wafer material and the measurement is started. After measuring 25 equally distributed spots on the wafer, the average sheet resistance is calculated in Ω/□.

### Solar Cell Structure

A contribution to achieving at least one of the above described objects is made by a solar cell obtainable from a process according to the invention. Preferred solar cells according to the invention are those which have a high efficiency, in terms of proportion of total energy of incident light converted into electrical energy output, and those which are light and durable. At a minimum, a solar cell includes: (i) front electrodes, (ii) a front doped layer, (iii) a p-n junction boundary, (iv) a back doped layer, and (v) soldering pads. The solar cell may also include additional layers for chemical/mechanical protection.

### Antireflective Layer

According to the invention, an antireflective layer may be applied as the outer layer before the electrode is applied to the front face of the solar cell. All antireflective layers known in the art and which are considered to be suitable in the context of the invention can be employed. Preferred antireflective layers are those which decrease the proportion of incident light reflected by the front face and increase the proportion of incident light crossing the front face to be absorbed by the wafer. Antireflective layers which give rise to a favorable absorption/reflection ratio, are susceptible to etching by the electroconductive paste, are otherwise resistant to the temperatures required for firing of the electroconductive paste, and do not contribute to increased recombination of electrons and holes in the vicinity of the electrode interface, are preferred. Preferred antireflective layers include, but are not limited to, SiNₓ, SiO₂, Al₂O₃, TiO₂ or mixtures of at least two thereof and/or combinations of at least two layers thereof. According to a preferred embodiment, the antireflective layer is SiNₓ, in particular where a silicon wafer is employed.

The thickness of antireflective layers is suited to the wavelength of the appropriate light. According to a preferred embodiment of the invention, the antireflective layers have a thickness of at least 20 nm, preferably at least 40 nm, and most preferably at least 60 nm. At the same time, the thickness is preferably no more than about 300 nm, more preferably no more than about 200 nm, and most preferably no more than about 90 nm.

### Passivation Layers

One or more passivation layers may be applied to the front and/or back side of the silicon wafer as an outer layer. The passivation layer(s) may be applied before the front electrode is formed, or before the antireflective layer is applied (if one is present). Preferred passivation layers are those which reduce the rate of electron/hole recombination in the vicinity of the electrode interface. Any passivation layer which is known in the art and which is considered to be suitable in the context of the invention can be employed. Preferred passivation layers according to the invention include, but are not limited to, silicon nitride, silicon dioxide and titanium dioxide. According to a more preferred embodiment, silicon nitride is used. It is preferred for the passivation layer to have a thickness of at least 0.1 nm, preferably at least 10 nm, and most preferably at least 30 nm. As the same time, the thickness is preferably no more than about 2μm, preferably no more than about 1 μm, and most preferably no more than about 200 nm.

### Additional Protective Layers

In addition to the layers described above, further layers can be added for mechanical and chemical protection. The cell can be encapsulated to provide chemical protection. According to a preferred embodiment, transparent polymers, often referred to as transparent thermoplastic resins, are used as the encapsulation material, if such an encapsulation is present. Preferred transparent polymers in this context are silicon rubber and polyethylene vinyl acetate (PVA). A transparent glass sheet may also be added to the front of the solar cell to provide mechanical protection to the front face of the cell. A back protecting material may be added to the back face of the solar cell to provide mechanical protection. Preferred back protecting materials are those having good mechanical properties and weather resistance. The preferred back protection material according to the invention is polyethylene terephthalate with a layer of polyvinyl fluoride. It is preferred for the back protecting material to be present underneath the encapsulation layer (in the event that both a back protection layer and encapsulation are present).

A frame material can be added to the outside of the solar cell to give mechanical support. Frame materials are well known in the art and any frame material considered suitable in the context of the invention may be employed. The preferred frame material according to the invention is aluminum.

### Method of Preparing a Solar Cell

A solar cell may be prepared by applying the electroconductive paste of the invention to an antireflection coating, such as silicon nitride, silicon oxide, titanium oxide or aluminum oxide, on the front side of a semiconductor substrate, such as a silicon wafer. A backside electroconductive paste is then applied to the backside of the solar cell to form soldering pads. An aluminum paste is then applied to the backside of the substrate, overlapping the edges of the soldering pads formed from the backside electroconductive paste, to form the BSF.

The electroconductive pastes may be applied in any manner known in the art and considered suitable in the context of the invention. Examples include, but are not limited to, impregnation, dipping, pouring, dripping on, injection, spraying, knife coating, curtain coating, brushing or printing or a combination of at least two thereof. Preferred printing techniques are ink-jet printing, screen printing, tampon printing, offset printing, relief printing or stencil printing or a combination of at least two thereof. It is preferred according to the invention that the electroconductive paste is applied by printing, preferably by screen printing. Specifically, the screens preferably have mesh opening with a diameter of about 40 μm or less (e.g., about 35 μm or less, about 30 μm or less). At the same time, the screens preferably have a mesh opening with a diameter of at least 10 μm.

The substrate is then subjected to one or more thermal treatment steps, such as, for example, conventional over drying, infrared or ultraviolet curing, and/or firing. In one embodiment the substrate may be fired according to an appropriate profile. Firing sinters the printed electroconductive paste so as to form solid electrodes. Firing is well known in the art and can be effected in any manner considered suitable in the context of the invention. It is preferred that firing be carried out above the T_{g} of the glass frit materials.

According to the invention, the maximum temperature set for firing is below about 900° C., preferably below about 860° C. Firing temperatures as low as about 800° C. have been employed for obtaining solar cells. Firing temperatures should also allow for effective sintering of the metallic particles to be achieved. The firing temperature profile is typically set so as to enable the burnout of organic materials from the electroconductive paste composition. The firing step is typically carried out in air or in an oxygen-containing atmosphere in a belt furnace. It is preferred for firing to be carried out in a fast firing process with a total firing time of at least 30 seconds, and preferably at least 40 seconds. At the same time, the firing time is preferably no more than about 3 minutes, more preferably no more than about 2 minutes, and most preferably no more than about 1 minute. The time above 600° C. is most preferably in a range from about 3 to 7 seconds. The substrate may reach a peak temperature in the range of about 700 to 900° C. for a period of about 1 to 5 seconds. The firing may also be conducted at high transport rates, for example, about 100-700 cm/min, with resulting hold-up times of about 0.5 to 3 minutes. Multiple temperature zones, for example 3-12 zones, can be used to control the desired thermal profile.

Firing of electroconductive pastes on the front and back faces can be carried out simultaneously or sequentially. Simultaneous firing is appropriate if the electroconductive pastes applied to both faces have similar, preferably identical, optimum firing conditions. Where appropriate, it is preferred for firing to be carried out simultaneously. Where firing is carried out sequentially, it is preferable for the back electroconductive paste to be applied and fired first, followed by application and firing of the electroconductive paste to the front face of the substrate.

### Measuring Properties of Electroconductive Paste

The electrical performance of a solar cell is measured using a commercial IV-tester “cetisPV-CTL1” from Halm Elektronik GmbH. All parts of the measurement equipment as well as the solar cell to be tested are maintained at 25° C. during electrical measurement. This temperature should be measured simultaneously on the cell surface during the actual measurement by a temperature probe. The Xe Arc lamp simulates the sunlight with a known AM1.5 intensity of 1000 W/m² on the cell surface. To bring the simulator to this intensity, the lamp is flashed several times within a short period of time until it reaches a stable level monitored by the “PVCTControl 4.313.0” software of the IV-tester. The Halm IV tester uses a multi-point contact method to measure current (I) and voltage (V) to determine the solar cell's IV-curve. To do so, the solar cell is placed between the multi-point contact probes in such a way that the probe fingers are in contact with the bus bars (i.e., printed lines) of the solar cell. The numbers of contact probe lines are adjusted to the number of bus bars on the cell surface. All electrical values were determined directly from this curve automatically by the implemented software package. As a reference standard, a calibrated solar cell from ISE Freiburg consisting of the same area dimensions, same wafer material, and processed using the same front side layout, was tested and the data was compared to the certificated values. At least five wafers processed in the very same way were measured and the data was interpreted by calculating the average of each value. The software PVCTControl 4.313.0 provided values for efficiency, fill factor, short circuit current, series resistance and open circuit voltage.

### Solar Cell Module

A plurality of solar cells according to the invention can be arranged spatially and electrically connected to form a collective arrangement called a module. Preferred modules according to the invention can have a number of arrangements, preferably a rectangular arrangement known as a solar panel. A large variety of ways to electrically connect solar cells, as well as a large variety of ways to mechanically arrange and fix such cells to form collective arrangements, are well known in the art. Preferred methods according to the invention are those which result in a low mass to power output ratio, low volume to power output ration, and high durability. Aluminum is the preferred material for mechanical fixing of solar cells according to the invention.

In one embodiment, multiple solar cells are connected in series and/or in parallel and the ends of the electrodes of the first cell and the last cell are preferably connected to output wiring. The solar cells are typically encapsulated in a transparent thermal plastic resin, such as silicon rubber or ethylene vinyl acetate. A transparent sheet of glass is placed on the front surface of the encapsulating transparent thermal plastic resin. A back protecting material, for example, a sheet of polyethylene terephthalate coated with a film of polyvinyl fluoride, is placed under the encapsulating thermal plastic resin. These layered materials may be heated in an appropriate vacuum furnace to remove air, and then integrated into one body by heating and pressing. Furthermore, since solar cells are typically left in the open air for a long time, it is desirable to cover the circumference of the solar cell with a frame material consisting of aluminum or the like.

The invention will now be described in conjunction with the following, non-limiting examples.

### EXAMPLE 1

A set of exemplary organic vehicles were prepared with varying amounts of lavandin oil (terpene compound) as set forth in Table 1 below. As a control, an organic vehicle comprising no lavandin oil was prepared. All values in Table 1 are based upon 100% total weight of the organic vehicle.

TABLE 1
Exemplary Organic Vehicles with Terpene Compound

| | Control | V1 | V2 | V3 | V4 | V5 |
|---|---|---|---|---|---|---|
| Lavandin oil (terpene) | 0 | 5 | 10 | 20 | 30 | 25 |
| Ethyl cellulose (resin) | 5.5 | 5.5 | 5.5 | 5.5 | 5.5 | 5.5 |
| Solvent | 80.5 | 74 | 69 | 59 | 49 | 55.5 |
| Thixotropic agent | 10.5 | 12 | 12 | 12 | 12 | 10.5 |
| Surfactant | 3.5 | 3.5 | 3.5 | 3.5 | 3.5 | 3.5 |

Exemplary electroconductive pastes were then prepared by mixing about 9 wt % of each organic vehicle, based upon 100% total weight of the electroconductive paste, with about 85 wt % silver particles having an average particle size d₅₀ of about 2 microns, about 5 wt % glass frit particles having an average particle size d₅₀ of about 2 microns, and about 1 wt % zinc oxide particles. The mixture was then milled using a three-roll mill with a first gap of about 120 microns and a second gap of about 60 microns and was passed through several times with progressively decreasing gaps (down to 20 microns for first gap and 10 microns for second gap) until it reached a homogenous consistency. The viscosity of the paste composition was then measured according to the method set forth herein.

Each exemplary paste and the control paste was then screen printed onto a silicon wafer at a speed of 150 mm/s, using screen 325 (mesh)*0.9 (mil, wire diameter)*0.6 (mil, emulsion thickness)*40 μm (finger line opening) (Calendar screen). The printed wafers were then dried at about 150° C. and fired at a profile with a peak temperature at about 800° C. for a few seconds in a linear multi-zone infrared furnace.

The printed lines were then photographed and measured for analysis. As set forth in Table 2 below, the height and width of each finger line was measured along its length using a Zeta-200 Optical Profiler, manufactured by Zeta Instruments of San Jose, Calif. The aspect ratio was also calculated by dividing the average height by the average width of the lines. As set forth herein, the lower the width of the printed line and the higher the height, the better the electrical performance of the printed line.

TABLE 2
Printing Performance of Exemplary Pastes P1-P5

| | Control | P1 | P2 | P3 | P4 | P5 |
|---|---|---|---|---|---|---|
| Average Line | 12.4 | 10.7 | 11.2 | 12.9 | 13.3 | 15.8 |
| Height (μm) | | | | | | |
| Height Stand. | 2.5 | 2.4 | 2.1 | 2.7 | 2.9 | 2.8 |
| Dev. (μm) | | | | | | |
| Average Line | 64.5 | 65.1 | 61.7 | 57.8 | 55.3 | 51.9 |
| Width (μm) | | | | | | |
| Width Stand. | 2.8 | 6.4 | 4.8 | 5.3 | 5.3 | 3.1 |
| Dev. (μm) | | | | | | |
| Aspect Ratio | 0.192 | 0.164 | 0.181 | 0.223 | 0.241 | 0.304 |

The exemplary pastes containing the organic vehicles with the highest amounts of terpene—V3, V4 and V5—exhibited the finest line width and highest line height, resulting in the highest aspect ratio. Pastes P3, P4 and P5 outperformed the control paste in all categories, exhibiting higher line height, narrower line width, and higher aspect ratio as compared to the control paste. The exemplary paste containing a smaller amount of terpene—V2—also exhibited a desirable decrease in line width.

The electrical performance of the solar cells printed with these pastes was also evaluated according to the parameters set forth herein. Specifically, the short circuit current (Isc, mA/cm²) and grid resistance (Rgrid) of each of the exemplary pastes and control paste was measured and categorized according to the following scheme: “−” indicates that a paste exhibited poor results, “+” indicates that a paste performed above average, “++” indicates that a paste performed well, “+++” indicates that a paste performed very well, and “++++” indicates that a paste performed exceptionally well.

TABLE 3
Electrical Performance of Exemplary Pastes P1-P5

| | Control | P1 | P2 | P3 | P4 | P5 |
|---|---|---|---|---|---|---|
| Isc | − | + | ++ | +++ | ++++ | +++ |
| Rgrid | − | + | ++ | +++ | ++++ | +++ |

The solar cells printed with the pastes having the highest amount of terpene (P3-P5) exhibited the best short circuit current and grid resistance. All pastes containing terpene exhibited improved electrical performance over the control paste.

### EXAMPLE 2

Another set of exemplary organic vehicles containing the same constituents in different amounts was prepared. As a control, an organic vehicle comprising no terpene was prepared. All values in Table 4 are based upon 100% total weight of the organic vehicle.

TABLE 4
Exemplary Organic Vehicles with Terpene Compound

| | Control | V6 | V7 | V8 |
|---|---|---|---|---|
| Lavandin oil (terpene) | 0 | 9 | 14 | 19 |
| Ethyl cellulose (resin) | 5 | 5 | 5 | 5 |
| Solvent | 84 | 75 | 70 | 65 |
| Thixotropic agent | 11 | 11 | 11 | 11 |

Exemplary electroconductive pastes were then prepared according to the same parameters and with the same materials as set forth in Example 1. The glass was a Pb—Si—P—B—W—O based glass frit. The efficiency of sample solar cells prepared with these pastes was then measured according to the parameters set forth herein. As set forth in Table 5 below, the efficiency of each composition is provided under the following scheme: “−−” indicates that the paste performed very poorly; “o” indicates that the paste performed moderately; “+” indicates that the paste performed well; “and ++” indicates that the paste performed very well.

TABLE 5
Electrical Performance of Exemplary Pastes P6-P8

| Example | Efficiency |
|---|---|
| Control | −− |
| P6 | o |
| P7 | + |
| P8 | ++ |

The exemplary paste containing the highest amount of terpene exhibited the best efficiency. All exemplary pastes exhibited improved efficiency over the control paste.

These and other advantages of the invention will be apparent to those skilled in the art from the foregoing specification. Accordingly, it will be recognized by those skilled in the art that changes or modifications may be made to the above described embodiments without departing from the broad inventive concepts of the invention. Specific dimensions of any particular embodiment are described for illustration purposes only. It should therefore be understood that this invention is not limited to the particular embodiments described herein, but is intended to include all changes and modifications that are within the scope and spirit of the invention.

1. An organic vehicle for an electroconductive paste composition, comprising:
at least about 0.5 wt % and no more than about 45 wt % of at least one of a natural essential oil, based upon 100% total weight of the organic vehicle;
at least about 0.5 wt % and no more than about 10 wt % of at least one resin;
an organic solvent; and
a thixotropic agent.

2. The organic vehicle according to claim 1, wherein the organic vehicle comprises at least about 5 wt % of the at least one natural essential oil and no more than about 35 wt %, based upon 100% total weight of the organic vehicle.

3. The organic vehicle according to claim 1, wherein the natural essential oil is at least one of olive oil, sunflower oil, corn oil, mustard oil, sesame oil, almond oil, peanut oil, canola oil, coconut oil, vegetable oil, and combinations thereof.

4. The organic vehicle according to claim 1, wherein the at least one natural essential oil is a terpene compound.

5. The organic vehicle according to claim 4, wherein the terpene is at least one of lavender oil, spike oil, lavender grosso oil, lavandin oil, linalool, linalyl acetate, geraniol, isoeugenol, farnesol, linoleic acid, eugenol, eitronellol, terpineol, terpineol isomers, pinenes, pinene isomers, and combinations thereof.

6. The organic vehicle according to claim 1, wherein the at least one resin is at least about 3 wt % and no more than about 8 wt %, based upon 100% total weight of the organic vehicle.

7. The organic vehicle according to claim 1, wherein the at least one resin is ethyl cellulose.

8. The organic vehicle according to claim 1, wherein the organic solvent is a glycol ether or ester alcohol, including at least one of carbitol, hexyl carbitol, texanol, butyl carbitol, butyl carbitol acetate, dimethyladipate glycol ether, diglyme, or butyl digylme and any combination thereof.

9. The organic vehicle according to claim 1, wherein the thixotropic agent is at least one of castor oil derivative, inorganic clays, polyamides, polyamide derivatives, fumed silica, carboxylic acid derivatives, fatty acid derivatives or any combination thereof.

10. The organic vehicle according to claim 1, wherein the thixotropic agent is at least about 1 wt %, and preferably at least about 7 wt %, and no more than about 15 wt %, and preferably no more than about 14 wt %, based upon 100% total weight of the organic vehicle.

11. The organic vehicle according to claim 1, further comprising a surfactant.

12. An electroconductive paste composition comprising:
conductive metallic particles;
glass frit; and
the organic vehicle according to claim 1.

13. The electroconductive paste composition according to claim 12, wherein the conductive metallic particles are at least one of silver, copper, gold, aluminum, nickel, platinum, palladium, molybdenum, and mixtures or alloys thereof.

14. The electroconductive paste composition according to claim 12, further comprising zinc oxide.

15. The electroconductive paste composition according to claim 12, wherein the conductive metallic particles are at least 35 wt %, preferably at least 50 wt %, more preferably at least 70 wt %, and most preferably at least 80 wt %, and no more than about 99 wt %, preferably no more than about 95 wt %, based upon 100% total weight of the paste.

16. The electroconductive paste composition according to claim 12, wherein the glass frit is at least about 0.5 wt %, preferably at least about 1 wt %, and no more than about 15 wt %, preferably no more than about 10 wt %, and most preferably no more than about 6 wt %, based upon 100% total weight of the paste.

17. The electroconductive paste composition according to claim 12, wherein the organic vehicle is at least about 0.1 wt %, preferably at least about 1 wt %, and most preferably at least about 5 wt %, and no more than about 20 wt %, preferably no more than about 15 wt %, based upon 100% total weight of the paste.

18. An electroconductive paste composition comprising:
conductive metallic particles;
glass frit;
an organic vehicle comprising:
at least about 0.5 wt % and no more than about 10 wt % of at least one resin, based upon 100% total weight of the organic vehicle,
an organic solvent, and
a thixotropic agent; and
at least about 0.01 wt % and no more than about 10 wt % of at least one natural essential oil, wherein the oil is added to the paste either together with the conductive metallic particles, glass frit, and organic vehicle or after the conductive metallic particles, glass frit, and organic vehicle have been combined.

19. A method of forming a solar cell comprising:
applying an electroconductive paste according to claim 12 to a surface of a silicon wafer; and
subjecting the electroconductive paste to one or more thermal treatment steps.

20. A solar cell formed according to the method of claim 19.
